(19) United States
(12) Patent Application Publication
(10) Pub. No.: US 2009/0048801 A1
(43) Pub. Date: Feb. 19, 2009

(54) Method and apparatus for generating thermal test vectors

(76) Inventor: Rajit Chandra, Cupertino, CA (US)

Correspondence Address: WALSTEIN BENNETT SMITH III, P. O. BOX 1668, GEORGETOWN, TX, 78628, US

(21) Appl. No.: 11/317,670

(22) Filed: Dec. 23, 2005

Related U.S. Application Data
(63) Continuation-in-part of application No. 11/180,353, filed on Jul. 13, 2005, now Pat. No. 7,401,304.
Application No. 11/180,353 is a continuation-in-part of application No. 10/979,957, filed on Nov. 3, 2004, now Pat. No. 7,194,711.
Application No. 10/979,957 is a continuation-in-part of application No. 11/039,737, filed on Jan. 20, 2005, now Pat. No. 7,203,920.
Application No. 11/039,737 is a continuation-in-part of application No. 11/198,467, filed on Aug. 5, 2005, now Pat. No. 7,383,520.
Application No. 11/198,467 is a continuation-in-part of application No. 10/979,957, filed on Nov. 3, 2004, now Pat. No. 7,194,711.
Application No. 10/979,957 is a continuation-in-part of application No. 11/198,470, filed on Aug. 5, 2005, now Pat. No. 7,353,471.
Application No. 11/198,470 is a continuation-in-part of application No. 10/979,957, filed on Nov. 3, 2004, now Pat. No. 7,194,711.
Application No. 10/979,957 is a continuation-in-part of application No. 11/215,783, filed on Aug. 29, 2005, now Pat. No. 7,458,052.
Application No. 11/215,783 is a continuation-in-part of application No. 10/979,957, filed on Nov. 3, 2004, now Pat. No. 7,194,711.
Application No. 10/979,957 is a continuation-in-part of application No. 11/078,047, filed on Mar. 11, 2005, now Pat. No. 7,191,413.
Application No. 11/078,047 is a continuation-in-part of application No. 10/979,957, filed on Nov. 3, 2004, now Pat. No. 7,194,711.
Application No. 10/979,957 is a continuation-in-part of application No. 11/039,737, filed on Jan. 20, 2005, now Pat. No. 7,203,920.
Application No. 11/039,737 is a continuation-in-part of application No. 10/979,957, filed on Nov. 3, 2004, now Pat. No. 7,194,711.
Application No. 10/979,957 is a continuation-in-part of application No. 10/979,957, filed on Nov. 3, 2004, now Pat. No. 7,194,711.
(60) Provisional application No. 60/751,376, filed on Dec. 17, 2005.
(60) Provisional application No. 60/734,372, filed on Nov. 7, 2005.
(60) Provisional application No. 60/718,138, filed on Sep. 16, 2005.
(60) Provisional application No. 60/587,313, filed on Jul. 13, 2004.
(60) Provisional application No. 60/599,098, filed on Aug. 5, 2004.
(60) Provisional application No. 60/599,278, filed on Aug. 5, 2004.
(60) Provisional application No. 60/598,987, filed on Aug. 5, 2004.
(60) Provisional application No. 60/605,889, filed on Aug. 30, 2004.
(60) Provisional application No. 60/689,592, filed on Jun. 10, 2005.
(60) Provisional application No. 60/552,375, filed on Mar. 11, 2004.
(60) Provisional application No. 60/658,323, filed on Mar. 3, 2005.
(60) Provisional application No. 60/658,324, filed on Mar. 3, 2005.
(60) Provisional application No. 60/539,727, filed on Jan. 28, 2004.
(60) Provisional application No. 60/599,098, filed on Aug. 5, 2004.
(60) Provisional application No. 60/539,727, filed on Jan. 28, 2004.

(51) Int. Cl. G01R 31/00; G01N 25/20

(52) U.S. Cl. 702/120; 324/537; 374/43; 702/117

(57) ABSTRACT

Temperature aware testing enables computation of thermal test vectors that are applied, via a tester, to a Device Under Test (DUT) to place various internal elements of the DUT at respective temperature operating points. The respective temperature operating points are selected to sensitize the DUT to measurements of selected temperature-dependent critical parameters, including frequency, leakage current behaviors, voltage drops, power profiles, thermal gradients, and absolute temperature. In operation, the thermal test vectors are applied to the DUT for a sufficient time for the DUT to reach thermal equilibrium, or alternatively for the internal elements to reach the respective temperature operating points. Subsequently critical parameter vectors are applied to enable measurement of one or more of the critical parameters. The critical parameter vectors are typically developed based in part on a multi-dimensional temperature map analysis of the DUT, using manufacturing process parameters and device physical design (or layout) information.

### CROSS REFERENCE TO RELATED APPLICATIONS

Priority benefit claims for this application are made in the accompanying Application Data Sheet (if any). To the extent permitted by the type of the instant application, this application incorporates by reference for all purposes the following applications, which are all owned by the owner of the instant application:

U.S. application Ser. No. ______ (Docket No. GDA.2005.08NP) filed herewith, by Rajit Chandra, and entitled Method and Apparatus for Thermally Aware Design Improvement;

U.S. application Ser. No. ______ (Docket No. GDA.2005.23NP) filed herewith, by Rajit Chandra, et al., and entitled Semiconductor Chip Design Having Thermal Awareness Across Multiple Sub-System Domains;

U.S. Provisional Application Ser. No. 60/751,376 (Docket No. GDA.2005.23) filed Dec. 17, 2005, by Rajit Chandra, et al., and entitled Semiconductor Chip Design Having Thermal Awareness Across Multiple Sub-System Domains;

U.S. Provisional Application Ser. No. 60/734,372 (Docket No. GDA.2005.24) filed Nov. 7, 2005, by Rajit Chandra, et al., and entitled Efficient Full-Chip Thermal Modeling and Analysis;

U.S. Provisional Application Ser. No. 60/718,138 (Docket No. GDA.2005.22) filed Sep. 16, 2005, by Rajit Chandra, and entitled Method and Apparatus for Temperature Assertion Based IC Design;

U.S. application Ser. No. 11/215,783 (Docket No. GRAD/011) filed Aug. 29, 2005, by Rajit Chandra, and entitled Method and Apparatus for Normalizing Thermal Gradients Over Semiconductor Chip Designs;

U.S. application Ser. No. 11/198,467 (Docket No. GRAD/009) filed Aug. 5, 2005, by Rajit Chandra, and entitled Method and Apparatus for Optimizing Thermal Management Systems Performance Using Full-Chip Thermal Analysis of Semiconductor Chip Designs;

U.S. application Ser. No. 11/198,470 (Docket No. GRAD/010) filed Aug. 5, 2005, by Rajit Chandra, and entitled Method and Apparatus for Using Full-Chip Thermal Analysis of Semiconductor Chip Designs to Compute Thermal Conductance;

U.S. application Ser. No. 11/180,353 (Docket No. GRAD/006) filed Jul. 13, 2005, by Ping Li, et al., and entitled Method and Apparatus for Thermal Modeling and Analysis of Semiconductor Chip Designs;

U.S. Provisional Application Ser. No. 60/689,592 (Docket No. GDA.2005.20) filed Jun. 10, 2005, by Rajit Chandra, and entitled Temperature-Aware Design Methodology;

U.S. application Ser. No. 11/078,047 (Docket No. GRAD/003) filed Mar. 11, 2005, by Rajit Chandra, et al., and entitled Method and Apparatus for Thermal Testing of Semiconductor Chip Designs;

U.S. Provisional Application Ser. No. 60/658,323 (Docket No. GDA.2005.09) filed Mar. 3, 2005, by Rajit Chandra, and entitled Method and Apparatus for Generating and Using Thermal Test Vectors;

U.S. Provisional Application Ser. No. 60/658,324 (Docket No. GDA.2005.08) filed Mar. 3, 2005, by Rajit Chandra, and entitled Method and Apparatus for Thermally Aware Design Improvement;

U.S. application Ser. No. 11/039,737 (Docket No. GRAD/007) filed Jan. 20, 2005, by Rajit Chandra, and entitled Method and Apparatus for Retrofitting Semiconductor Chip Performance Analysis Tools with Full-Chip Thermal Analysis Capabilities; and

U.S. application Ser. No. 10/979,957 (Docket No. GRAD/012) filed Nov. 3, 2004, by Rajit Chandra, and entitled Method and Apparatus for Full-Chip Thermal Analysis of Semiconductor Chip Designs.

### BACKGROUND

1. Field

Advancements in integrated circuit test vectors are needed to provide improvements in performance, efficiency, and utility of use in integrated circuit testing.

2. Related Art

Unless expressly identified as being publicly or well known, mention herein of techniques and concepts, including for context, definitions, or comparison purposes, should not be construed as an admission that such techniques and concepts are previously publicly known or otherwise part of the prior art. All references cited herein (if any), including patents, patent applications, and publications, are hereby incorporated by reference in their entireties, whether specifically incorporated or not, for all purposes. Nothing herein is to be construed as an admission that any of the references are pertinent prior art, nor does it constitute any admission as to the contents or date of actual publication of these documents.

### SUMMARY

The invention may be implemented in numerous ways, including as a process, an article of manufacture, an apparatus, a system, a composition of matter, and a computer readable medium such as a computer readable storage medium or a computer network wherein program instructions are sent over optical or electronic communication links. In this specification, these implementations, or any other form that the invention may take, may be referred to as techniques. In general, the order of the steps of disclosed processes may be altered within the scope of the invention. The Detailed Description provides an exposition of one or more embodiments of the invention that enable improvements in performance, efficiency, and utility of use in the field identified above. The Detailed Description includes an Introduction to facilitate the more rapid understanding of the remainder of the Detailed Description. As is discussed in more detail in the Conclusions, the invention encompasses all possible modifications and variations within the scope of the issued claims, which are appended to the very end of the issued patent.

Temperature aware testing enables computation of thermal test vectors that are applied, via a tester, to a Device Under Test (DUT) to place various internal elements of the DUT at respective temperature operating points. The respective temperature operating points are selected to sensitize the DUT to measurements of selected temperature-dependent critical parameters, including frequency, leakage current behaviors, voltage drops, power profiles, thermal gradients, and absolute temperature. In operation, the thermal test vectors are applied to the DUT for a sufficient time for the DUT to reach thermal equilibrium, or alternatively for the internal elements to reach the respective temperature operating points. Subsequently critical parameter vectors are applied to enable measurement of one or more of the critical parameters. The critical parameter vectors are typically developed based in part on a multi-dimensional temperature map analysis of the DUT, using manufacturing process parameters and device physical design (or layout) information.

### BRIEF DESCRIPTION OF DRAWINGS

Various embodiments of the invention are disclosed in the following detailed description and the accompanying drawings.

FIG. 1 illustrates an embodiment of a thermal test vector system including a Device Under Test (DUT).

FIG. 2 illustrates an embodiment of a flow diagram for generating and applying thermal test vectors.

FIG. 3 illustrates an embodiment of a computer system for generating thermal test vectors

### DETAILED DESCRIPTION

A detailed description of one or more embodiments of the invention is provided below along with accompanying figures that illustrate the principles of the invention. Some of the embodiments or variations thereof may be characterized as “notable.” The invention is described in connection with the embodiments, which are understood to be merely illustrative and not limiting. The invention is expressly not limited to or by any or all of the embodiments herein (notable or otherwise). The scope of the invention is limited only by the claims appended to the end of the issued patent and the invention encompasses numerous alternatives, modifications and equivalents. Numerous specific details are set forth in the following description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured.

### Introduction

This introduction is included only to facilitate the more rapid understanding of the Detailed Description. The invention is not limited to the concepts presented in the introduction, as the paragraphs of any introduction are necessarily an abridged view of the entire subject and are not meant to be an exhaustive or restrictive description. For example, the introduction that follows provides overview information limited by space and organization to only certain embodiments. There are in fact many other embodiments, including those to which claims will ultimately be drawn, which are discussed throughout the balance of the specification.

Temperature aware testing enables computation of thermal test vectors that are applied, via a tester, to a DUT that is typically an integrated circuit (also referred to as a die or chip, according to context), to place various internal elements of the DUT at respective temperature operating points. The respective temperature operating points are selected to sensitize the DUT to measurements of selected temperature-dependent critical parameters, including frequency (or conversely timing paths), leakage current behaviors, voltage drops, power profiles, thermal gradients, and absolute temperature. In operation, the thermal test vectors (or thermal stimulation vectors) are applied to the DUT for a sufficient time for the DUT to reach thermal equilibrium, or alternatively for the internal elements to reach the respective temperature operating points. Subsequently critical parameter vectors are applied to enable measurement of one or more of the critical parameters. The thermal stimulation vectors, the critical parameter vectors, or both (according to embodiment) are developed based in part on a multi-dimensional temperature map analysis of the DUT, using manufacturing process parameters, device physical design (or layout) information, and initial power information. Typically the vectors are applied at least in part in an at-speed manner (often referred to as “AC testing”), and timing path measurements are according to a “double-clock” style test. Various implementations provide for alternating (or interleaving) application of thermal stimulation vectors and critical parameter vectors.

Some parameters of some components of the chip have positive temperature correlation, i.e. as temperature increases a corresponding parameter of a component increases, while other parameters exhibit negative temperature correlation. In some illustrative scenarios transistors consume more power (due to leakage current, for example) as temperature increases, while some metal-based interconnects may consume less power as temperature increases (due to increased resistance). Frequently resistive (or DC-power-consuming) elements consume more power as temperature increases. Thermally aware testing accounts for positive and negative temperature correlation behaviors, providing more accurate analysis of expected behavior than conventional techniques.

### Particular Thermal Test Vector System Embodiments

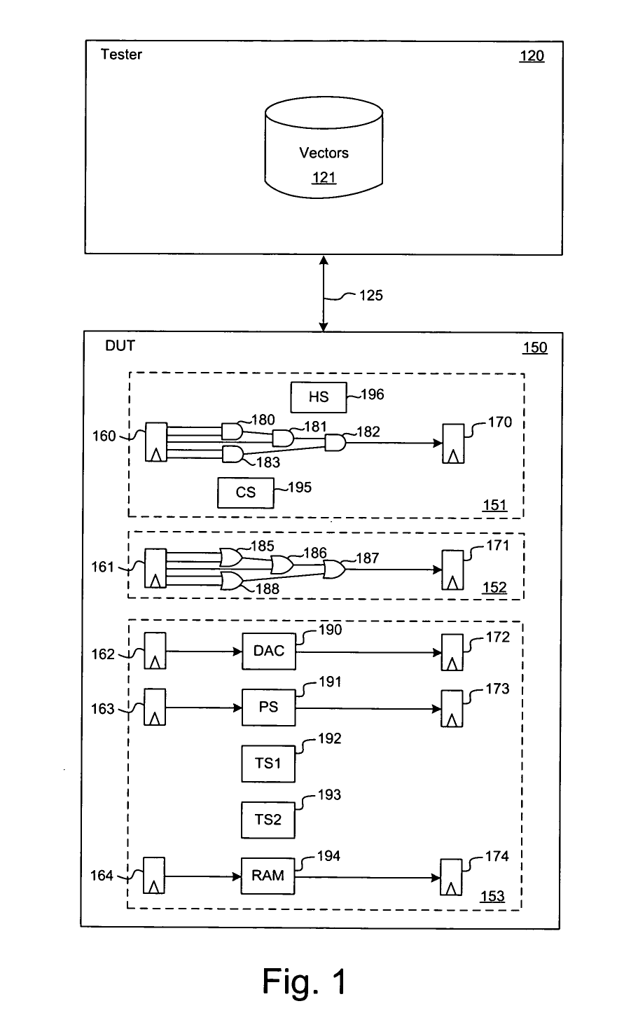

FIG. 1 illustrates an embodiment of a thermal test vector system including DUT 150 coupled to Tester 120 via Tester-DUT Coupling 125. The tester typically includes non-volatile storage for test patterns often referred to as test vectors or simply “vectors”, as illustrated by Test Vector Repository 121. Selected details of the DUT are illustrated, all of which are typically included on one or more integrated circuit die included in the DUT. These details are illustrative only, and representative of only one of a multiplicity of possible arrangements of components and circuitry on devices to be tested and characterized according to various embodiments.

With respect to the illustrative scenario, regions of the DUT include Unadjusted Vt Elements 151, Low Vt Elements 152, and Special Elements 153. Unadjusted Vt Elements 151 includes Flip-Flop (FF) storage elements (Source FFs 160 and Destination FFs 170) and logic gates (AND Gates 180-183) representative of a plurality of logic paths implemented with transistors having threshold voltages that are the default for a manufacturing flow. Unadjusted Vt Elements 151 further includes thermal structures such as Heat Structure (HS) 196 (representative of optional heat generators) and Cooling Structure (CS) 195 (representative of optional heat removers). Low Vt Elements 152 includes storage elements (Source FFs 161 and Destination FFs 171), and gates (Low Vt OR Gates 185-188) representative of a plurality of logic paths implemented with transistors having threshold voltages that are purposefully reduced compared to (or lower than) the manufacturing flow norm.

Special Elements 153 includes elements having special thermal properties (such as Thermal Structure (TS) 1 and TS2 as 192 and 193 respectively). TS1 192 is similar to CS 195, and is representative of a manufactured element (such as a collection of plated holes, or vias) provided to enable localized cooling of a portion of the integrated circuit die. TS2 193 is similar to HS 196, and is representative of an element provided to intentionally heat a section of the die. Special Elements 153 further includes elements consuming Direct Current (DC) power (such as Digital to Analog Converter (DAC) 190, Power Supply (PS) 191, and Random Access read/write Memory (RAM) 194). The special elements further include Source FFs 162-164 and Destination FFs 172-174. Those of ordinary skill in the art will recognize that logic paths often feed back onto themselves, such that any portion of Source FFs 160-164 may be the same FFs as any corresponding portion of Destination FFs 170-174. For example, Source FFs 162 and Destination FFs 172 may be the same FFs.

In operation, vectors from Test Vector Repository 121 are applied by Tester 120 to DUT 150, and the tester gathers response information from the DUT to determine a pass/fail indication for a test. One or more test vector patterns may be applied and respective pass/fail indications may be combined for an overall indication of manufacturing correctness of the DUT. In some usage scenarios characterization information (as may be represented by a graph, chart or plot) is collected in addition to or instead of the pass/fail indications. In some usage scenarios a shape, slope, or other similar quality of the graph, chart, or plot serves as a pass/fail indicator. Portions of the vectors typically sensitize specific paths through the logic of the DUT, such as a path through elements Source FF 160 and AND Gate 183 to Destination FF 170. Alternatively a path through Source FF 160 and AND Gates 180-182 to Destination FF 170 may be exercised. Similarly, paths through Low Vt Elements 152 and Special Elements 153 may be tested by selectively controlling and observing behaviors of included elements.

Test vectors are typically developed to exercise paths of interest during normal (i.e. not while being tested) operation of the DUT. In some normal operation scenarios AND Gate 183 may be operating at a significantly higher temperature than the other elements of Unadjusted Vt Elements 151 (such as due to physical proximity to a high-power element). Furthermore, the underlying transistor technology, such as Complementary Metal-Oxide Semiconductor (CMOS), may be such that higher temperatures result in longer gate propagation delays. Thus the timing path through AND Gate 183 may be significantly longer than a timing path through AND Gates 180-182 in series, even though the AND Gate 183 path is only through a single element.

Test vectors are also typically developed to determine if structures having special thermal properties (such as TS1 192, TS2 193, HS 196, and CS 195) are manufactured properly. For example, CS 195, if manufactured properly, may eliminate or mitigate any substantial temperature increase of AND Gate 183 that would otherwise occur if the thermal structure did not exist or were manufactured incorrectly. As another example, HS 196, if manufactured properly, may heat AND Gates 180-182 such that the corresponding path delay is increased sufficiently to prevent any hold time errors that would otherwise occur. As described in the “Thermal Test Vector Generation and Use” section, Test Vector Repository 121 may include vectors developed to create the aforementioned localized heating conditions, and to test selected affected paths, as well as vectors developed to test selected thermal structures.

Those of ordinary skill in the art will realize that other semiconductors technologies, such as Bipolar Complementary Metal-Oxide Semiconductor (BiCMOS), Gallium Arsenide (GaAs), and Bipolar, in addition to CMOS, may also be analyzed according to various embodiments. Furthermore, various packaging techniques such as Ball Grid Array (BGA), Ceramic BGA (CBGA), and Plastic BGA (PBGA); and die attach technologies including Controlled Collapse Chip Connection (C4), thermal epoxy with wire bonding, may be accounted for in the analysis.

### Thermal Test Vector Generation and Use

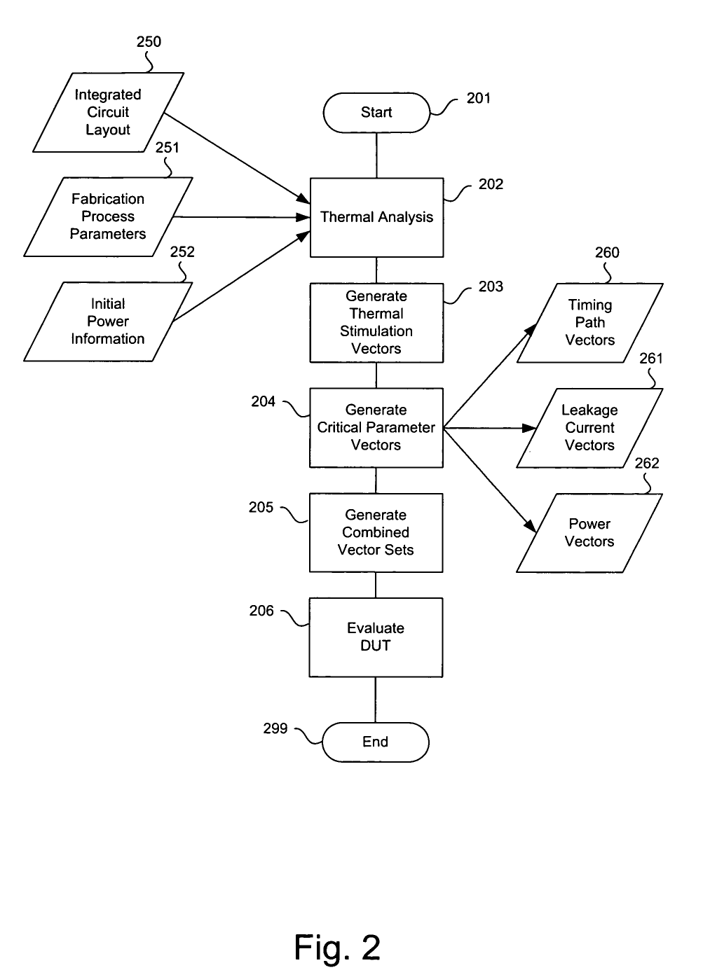

FIG. 2 illustrates an embodiment of a flow diagram for generating and applying thermal test vectors, typically maintained in Test Vector Repository 121. Generally, a thermal analysis is performed based on a description of a design of the die (often referred to as the layout of the die), taking into account expected results of a manufacturing flow (often in the form of process parameters). The thermal analysis provides information used in turn to generate thermal stimulation vectors that when applied to a manufactured version of the die result in various portions of the die attaining desired temperatures. Subsequently test vectors are generated to measure various critical parameters. The critical parameters include any combination of maximum and minimum operating frequency, leakage current, power consumption, temperature gradient, absolute temperature, and other related metrics. The critical parameter test vectors are then appended to appropriately selected thermal stimulation vectors to produce combined vector sets having a first portion generated to set portions of the circuit to desired temperatures, followed by a second portion generated to measure one or more critical parameters. In the aforementioned manner, thermal analysis is used to provide test vectors enabling specific measurement of various chip performance metrics while accounting for effects of temperature on various elements of the die.

More specifically, flow begins (“Start” 201) and then a thermal analysis or simulation of expected (or predicted) thermal behavior of an integrated circuit is performed (“Thermal Analysis” 202). A machine-readable (or computer software readable) and typically Computer Aided Design (CAD) generated representation of the integrated circuit design (“Integrated Circuit Layout” 250) is an input to the thermal analysis. A machine-readable description of various aspects of a manufacturing flow to be used to construct the integrated circuit, including any combination of semiconductor wafer processing information, package and die attach characteristics, and optional heatsink data (“Fabrication Process Parameters” 251) is also supplied to the thermal analysis. In some embodiments a description of initial heat-producing behavior of elements of the die is also provided to the thermal analysis (“Initial Power Information” 252). The initial power information may be derived from logic, circuit, or other similar simulation techniques, or it may be input more directly by design personnel, such as via a text file. The initial power information may take the form of any combination of effective resistance, current draw, absolute or relative power, and switching activity factors, varying by embodiment.

In some embodiments the thermal analysis uses the initial power information as final power information, while in other embodiments the thermal analysis iterates to final power information for elements of the die, using the initial power information as a starting point. In typical embodiments the power information (either initial values, interim iterative values, or final values) is combined with a two or three dimensional analysis of thermal propagation behavior of the die in the context of package, die attach, and optional heatsink thermal properties. A resultant multi-dimensional temperature profile is then used (in iterative embodiments) to determine new power values. If iteration closure, as measured by temperature or power changes (according to embodiment) from a previous iteration is reached, then the iteration process is complete with resultant temperature profile information available as results of the thermal analysis.

Results of the thermal analysis include expected operating temperatures for various elements of the die, such as temperatures of AND Gates 180-183, Low Vt OR Gates 185-188, and other elements of FIG. 1. The results may also include a thermal diagram or temperature gradient map, indicating equi-thermal lines of identical temperature superimposed on a representation of the physical layout of the integrated circuit. Alternatively, a listing of elements and respective temperatures may be provided in a tabular format. Any combination of the results may be provided in human-readable and machine-readable representations.

In some embodiments design personnel inspect the results and selectively pass all or portions of the results to guide generation of test vectors to place various elements of the integrated circuit at respective thermal operating points, as determined by the thermal analysis. In some embodiments the results are automatically passed, in machine-readable form, from the thermal analysis process to the following thermal stimulation vector generation process (“Generate Thermal Stimulation Vectors” 203).

The generated thermal stimulation vectors selectively exercise portions of the elements of the integrated circuit (or die) in order to heat (and to avoid heating) various portions of the die according to the thermal analysis results. For example, a first set of thermal stimulation vectors are targeted to place elements of Unadjusted Vt Elements 151, Low Vt Elements 152, and Special Elements 153 in a relatively low temperature state, in order to measure fastest timing path behavior. In some implementations this is accomplished by generating test vectors that when provided to the DUT minimize switching of Unadjusted Vt Elements 151 and Low Vt Elements 152 and reduce or eliminate DC power consumed by Special Elements 153. Continuing with the example, a second set of thermal stimulation vectors are similar to the first, except that Low Vt OR Gate 188 is targeted to be heated by elements in close physical proximity, such as Low Vt OR Gates 185-187, and DAC 190. In some implementations the resulting test vectors maximize switching of Low Vt OR Gates 185-187 and increase DC power consumed by DAC 190 by operating the DAC at a relatively high duty ratio.

The generated thermal stimulation vectors also selectively target driving portions of the die to relatively higher and lower temperatures in order to verify proper operation or manufacturing of special thermal structures (such as TS1 192 and TS2 193). For example, a third set of thermal stimulation vectors target heating in one or more elements (such as PS 191) that are physically near and are intended to be cooled by TS1 192. In some implementations the resulting test vectors maximum DC power consumption (or heat generation) of PS 191 by maximizing use of the PS. Continuing with the example, a fourth set of thermal stimulation vectors target relatively low temperature operation of elements (such as RAM 194) that are in close physical proximity to and intended to be heated by TS2 193. In some implementations the resulting test vectors minimize use of the RAM to reduce its operating temperature.

Any number and combination of thermal stimulation vector sets may be generated, targeting various portions of the die, and further may be selectively generated according to operating modes of circuitry on the die or similar conditioning, according to various embodiments. In some embodiments design personnel may provide guidance to the generation of thermal stimulation vectors, according to implementation requirements such as quality control metrics, guard bands, and similar parameters.

Flow then proceeds to generate test vectors targeting measurements of one or more critical parameters (“Generate Critical Parameter Vectors” 204). The critical parameters are typically representative of a marginality of performance or similar behavior, and include best and worst circumstances of timing (“Timing Path Vectors” 260), leakage (“Leakage Current Vectors” 261), power (“Power Vectors” 262), voltage drop, temperature gradient, and absolute temperature. Any number and combination of critical parameter measurement vector sets may be generated, targeting various parameters on various portions of the die, according to embodiment.

In some embodiments the vector sets are implemented for at-speed functional tests, and in some embodiments the vector sets are implemented for at speed double-clock tests. In some embodiments the double-clock tests include scanning in a sensitizing pattern into storage elements (such as FFs 160-164 and 170-174) via one or more serial scan chains. Then two functional clocks are supplied at an operational frequency (typically a high frequency), followed by scanning out results for comparison to a standard pattern for pass/fail determination.

The generated critical parameter vectors are then appropriately combined with the thermal stimulation vectors (“Generate Combined Vector Sets” 205), producing complete test vector sets. Each vector set typically measures (or provides a pass/fail indication for) at least one critical parameter after using thermal stimulation vectors to place elements of the DUT at desired operating temperatures. For example, the second set of thermal stimulation vectors previously described (targeting heating Low Vt OR Gate 188) would be prefixed to a critical parameter vector set sensitizing a critical timing path measurement that includes the heated target gate.

In various embodiments the combining is under any combination of program control and explicit designer control. Resultant test vector sets are typically in machine-readable form compatible with Test Vector Repository 121. Flow then proceeds to test a manufactured version of the integrated circuit (“Evaluate DUT” 206) using any combination of the combined vector sets, as represented by DUT 150 coupled to Tester 120 (see FIG. 1). In typical usage scenarios, many instances of the integrated circuit are tested or characterized in batch mode using the same sets of combined test vectors. Each of the instances is inserted into a test fixture (not shown in FIG. 1) coupled to the tester, and one or more of the combined vector sets from Test Vector Repository 121 are applied and test results gathered. Test pass/fail indications may be stored and supplied to test and manufacturing personnel. Vector generation and usage flow is then complete (“End” 299).

In some usage scenarios, the layout analyzed when generating the vectors might not correspond directly to the layout used to manufacture a device eventually tested by the vectors. Insubstantial changes to the layout (i.e. those not affecting logical functionality, for example) could be made to the layout in between when the vectors are generated and when the DUT is manufactured. Substantial changes might also be made to the layout, but the manufactured device could still be expected to pass all or portions of the vectors (or the vectors could be used to characterize the manufactured device), as those of ordinary skill in the art will recognize.

In some embodiments generation, application, or both, of vectors to drive the DUT to operate at a specific thermal profile (“Generate Thermal Stimulation Vectors” 203) is omitted. Instead the thermal analysis results are directly used to generate vectors to measure selected critical parameters (“Generate Critical Parameter Vectors” 204). The thermal map information enables determining critical parameters in the context of thermal behavior of the elements of the die, rather than assuming all of the elements are operating at identical (worst or best-case) temperatures. For example, Low Vt OR Gate 188 may be heated to a much higher relative temperature than surrounding elements during normal expected operation of the integrated circuit. Deriving critical parameter vectors (such as timing path vectors) using the relative temperature information of Low Vt OR Gate 188 enables accurately determining that the delay path including Low Vt OR Gate 188 is more critical (slower, for example) than the delay path including Low Vt OR Gates 185-187 in series. Similarly, knowledge that Low Vt OR Gates 185-187 are operating at a relatively lower temperature, and hence inserting a relatively lower delay, may enable detection of a hold time problem (a path too fast) between Source FFs 161 and Destination FFs 171 via Low Vt OR Gates 185-187 in series.

In some embodiments rather than targeting vectors for use on a tester, vectors are generated for use in a simulation of the die, such as a circuit, logic, or other similar tool to predict the behavior of the die under varying stimuli and conditions. Such embodiments typically also modify models associated with the elements of the die and the modified models are used by the simulation program to determine intermediate and final results of the simulation. The modifications are to account for various combinations of static and dynamic temperature operating points of the elements of the die. The simulation stimulus vectors are thus generated with knowledge of and in the context of the modified models, enabling temperature aware simulation with patterns sensitized to predicted temperature profiles and gradients. Similarly, simulation expected results allow verification of expected temperature related behaviors.

### Thermal Test Vector Generation System

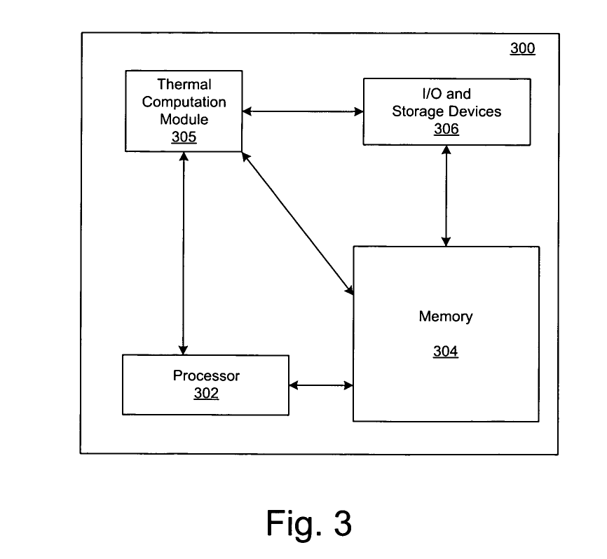

FIG. 3 illustrates an embodiment of a Computer System 300 for generating thermal test vectors. The Computer System is a general purpose computing system such as a Personal Computer (PC), Workstation, or Server, and includes a Processor 302, a Memory 304, a Thermal Computation Module 305 and various Input/Output (I/O) and Storage Devices 306. The I/O and Storage Devices module includes any combination of a display, a keyboard, a mouse, a modem, a network connection, a magnetic disk drive, an optical disk drive, and similar devices. In some embodiments several of the aforementioned procedures (such as “Thermal Analysis” 202, “Generate Thermal Stimulation Vectors” 203, “Generate Critical Parameter Vectors” 204, and optionally portions of “Generate Combined Vector Sets” 205) are implemented via Thermal Computation Module 305.

In some embodiments Thermal Analysis Module 305 is implemented as a physical device or subsystem that is coupled to a processor through a communication channel. Alternatively, the Thermal Computation Module may be implemented by one or more software applications (or even a combination of software and hardware, e.g., using Application Specific Integrated Circuits (ASIC)), where the software is loaded from a storage medium (such as from I/O and Storage Devices 306) and operated by Processor 302 in Memory 304 of Computer System 300. Additionally, the software may run in a distributed or partitioned fashion on two or more computing devices similar to Computer System 300. Thus, in some embodiments, Thermal Computation Module 305 for thermal computations relating to semiconductor chip design and testing, described herein with reference to the preceding figures, can be stored on a computer readable medium or carrier (e.g., RAM, magnetic or optical drive or diskette, and similar storage media).

### Conclusion

Although the foregoing embodiments have been described in some detail for purposes of clarity of understanding, the invention is not limited to the details provided. There are many ways of implementing the invention. The disclosed embodiments are illustrative and not restrictive.

It will be understood that many variations in construction, arrangement and use are possible consistent with the teachings and within the scope of the claims appended to the issued patent. For example, interconnect and function-unit bit-widths, clock speeds, and the type of technology used may generally be varied in each component block. The names given to interconnect and logic are merely illustrative, and should not be construed as limiting the concepts taught. The order and arrangement of flowchart and flow diagram process, action, and function elements may generally be varied. Also, unless specifically stated to the contrary, the value ranges specified, the maximum and minimum values used, or other particular specifications (such as specific semiconductor technology), are merely those of the illustrative embodiments, may be expected to track improvements and changes in implementation technology, and should not be construed as limitations.

Functionally equivalent techniques known to those of ordinary skill in the art may be employed instead of those illustrated to implement various components, sub-systems, functions, operations, routines, and sub-routines. It is also understood that many design functional aspects may be carried out in either hardware (i.e., generally dedicated circuitry) or software (i.e., via some manner of programmed controller or processor), as a function of implementation dependent design constraints and the technology trends of faster processing (which facilitates migration of functions previously in hardware into software) and higher integration density (which facilitates migration of functions previously in software into hardware). Specific variations may include, but are not limited to: hardware acceleration of test vector generation; and other variations to be expected when implementing the concepts taught herein in accordance with the unique engineering and business constraints of a particular application.

The embodiments have been illustrated with detail and environmental context well beyond that required for a minimal implementation of many of aspects of the concepts taught. Those of ordinary skill in the art will recognize that variations may omit disclosed components or features without altering the basic cooperation among the remaining elements. It is thus understood that much of the details disclosed are not required to implement various aspects of the concepts taught. To the extent that the remaining elements are distinguishable from the prior art, components and features that may be so omitted are not limiting on the concepts taught herein.

All such variations in design comprise insubstantial changes over the teachings conveyed by the illustrative embodiments. It is also understood that the concepts taught herein have broad applicability to other computing and networking applications, and are not limited to the particular application or industry of the illustrated embodiments. The invention is thus to be construed as including all possible modifications and variations encompassed within the scope of the claims appended to the issued patent.

What is claimed is:

1. A method of testing integrated circuits, the method including the steps of:
stimulating an integrated circuit device under test with thermal test vectors; and
confirming that a performance metric is within an expected range.

2. The method of claim 1, wherein the thermal test vectors include thermal stimulation vectors.

3. The method of claim 2, wherein application of the thermal stimulation vectors to the device under test results in the device under test operating in a temperature profile including at least one of:
a maximum temperature gradient profile,
a minimum temperature gradient profile,
a maximum absolute temperature profile, and
a minimum absolute temperature profile.

4. The method of claim 2, wherein application of the thermal stimulation vectors to the device under test results in a portion of an integrated circuit die included in the device under test operating in a temperature profile including at least one of:
a maximum temperature gradient profile,
a minimum temperature gradient profile,
a maximum absolute temperature profile, and
a minimum absolute temperature profile.

5. The method of claim 1, wherein the thermal test vectors include performance metric measurement vectors to measure the performance metric.

6. The method of claim 1, wherein the performance metric includes at least one of:
a worst-case timing path performance metric,
a best-case timing path performance metric,
a worst-case threshold voltage performance metric,
a best-case threshold voltage performance metric,
a worst-case cross talk noise performance metric,
a best-case cross talk noise performance metric,
a worst-case parametric degradation of circuits performance metric,
a best-case parametric degradation of circuits performance metric,
a worst-case leakage current performance metric,
a best-case leakage current performance metric,
a worst-case voltage drop performance metric,
a best-case voltage drop performance metric,
a worst-case power performance metric,
a best-case power performance metric,
a highest-gradient temperature performance metric,
a lowest-gradient temperature performance metric,
a highest temperature performance metric, and
a lowest temperature performance metric.

7. The method of claim 1, wherein the thermal test vectors are generated based in part on a thermal analysis of a model packaged integrated circuit having a selected package physical design.

8. The method of claim 7, wherein the thermal test vectors include at least a first set and a second set of thermal test vectors generated in accordance with the model packaged integrated circuit being subjected respectively to at least a first and a second ambient environment.

9. The method of claim 1, wherein the thermal test vectors include at least a first set of thermal test vectors generated based in part on a thermal analysis of a first model integrated circuit that is unpackaged and a second set of thermal test vectors generated based in part on a thermal analysis of a second model integrated circuit packaged according to a selected package physical design.

10. The method of claim 1, wherein the thermal test vectors include at least a first set of thermal test vectors generated based in part on a thermal analysis of a first model packaged integrated circuit having a first package physical design and a second set of thermal test vectors generated based in part on a thermal analysis of a second model packaged integrated circuit having a second package physical design.

11. The method of claim 10, wherein the device under test is an unpackaged integrated circuit die.

12. The method of claim 7, wherein the thermal analysis accounts for temperature correlated behavior of elements of the device under test.

13. The method of claim 12, wherein the temperature correlated behavior includes a negative temperature correlation and at least one performance metric of at least one of the elements of the device decreases as temperature of the at least one element increases.

14. The method of claim 12, wherein the temperature correlated behavior includes a positive temperature correlation and at least one performance metric of at least one of the elements of the device increases as temperature of the at least one element increases.

15. The method of claim 7, wherein the thermal analysis is a multi-dimensional spatial analysis.

16. The method of claim 15, wherein the multi-dimensional spatial analysis includes a two-dimensional analysis.

17. The method of claim 15, wherein the multi-dimensional spatial analysis includes a three-dimensional analysis.

18. The method of claim 7, wherein the thermal analysis is a time-invariant multi-dimensional spatial analysis.

19. The method of claim 7, wherein the thermal analysis is a time-varying multi-dimensional spatial analysis.

20. The method of claim 7, wherein the package physical design of the device under test is manufactured according to the selected package physical design.

21. The method of claim 20, wherein the thermal test vectors include at least a first set and a second set of thermal test vectors generated in accordance with the model packaged integrated circuit being subjected respectively to at least a first and a second ambient environment.

22. The method of claim 20, wherein the selected package physical design is a first package physical design, and the package of the device under test is manufactured according to a second package physical design.

23. The method of claim 22, wherein the thermal test vectors include at least a first set and a second set of thermal test vectors generated in accordance with the model packaged integrated circuit being subjected respectively to at least a first and a second ambient environment.

24. The method of claim 22, wherein the first package physical design specifies a first package that is different than a second package specified by the second package physical design.

25. The method of claim 22, wherein the first package physical design specifies a first heatsink that is different than a second heatsink specified by the second package physical design.

26. The method of claim 25, wherein the thermal test vectors include at least a first set and a second set of thermal test vectors generated in accordance with the model packaged integrated circuit being subjected respectively to at least a first and a second ambient environment.

27. The method of claim 7, wherein a die included in the device under test is fabricated according to a mask set developed assuming the die would be embodied in a package manufactured according to the selected package physical design.

28. The method of claim 27, wherein the thermal test vectors include at least a first set and a second set of thermal test vectors generated in accordance with the model packaged integrated circuit being subjected respectively to at least a first and a second ambient environment.

29. The method of claim 27, wherein the die is embodied in a package manufactured according to the selected package physical design.

30. The method of claim 29, wherein the thermal test vectors include at least a first set and a second set of thermal test vectors generated in accordance with the model packaged integrated circuit being subjected respectively to at least a first and a second ambient environment.

31. The method of claim 7, wherein logical functionality of the device under test and logical functionality of the packaged integrated circuit are equivalent.

32. The method of claim 1, wherein the device under test is an unpackaged integrated circuit die.

33. The method of claim 32, wherein the act of stimulating the device under test is performed at wafer probe.

34. The method of claim 1, wherein:
the device under test is a packaged electronic component; and
the act of stimulating the device under test is performed with an integrated circuit tester.

35. The method of claim 1, wherein:
the device under test is a simulation model of a portion of a packaged electronic component; and
the act of stimulating the device under test is performed with a simulator.

36. The method of claim 1, wherein the expected range is defined in part by a minimum value.

37. The method of claim 1, wherein the expected range is defined in part by a maximum value.

38. The method of claim 1, wherein the expected range is defined in part by maximum and minimum values.

39. A method including the steps of:
analyzing a layout specifying a plurality of components of an integrated circuit to determine operating temperatures for each of the components; and
generating thermal stimulation vectors adapted to be applied to operate the components of a fabricated instance of the integrated circuit at respective desired temperatures.

40. The method of claim 39, wherein the components include active components.

41. The method of claim 39, wherein the components include passive components.

42. The method of claim 39, wherein the respective desired temperatures are determined based on at least one of a criterion including
a worst-case timing path criterion,
a best-case timing path criterion,
a worst-case threshold voltage criterion,
a best-case threshold voltage criterion,
a worst-case cross talk noise criterion,
a best-case cross talk noise criterion,
a worst-case parametric degradation of circuits criterion,
a best-case parametric degradation of circuits criterion,
a worst-case leakage current criterion,
a best-case leakage current criterion,
a worst-case voltage drop criterion,
a best-case voltage drop criterion,
a worst-case power criterion,
a best-case power criterion,
a highest-gradient temperature criterion,
a lowest-gradient temperature criterion,
a highest temperature criterion, and
a lowest temperature criterion.

43. The method of claim 42, wherein the at least one criterion is with respect to at least one of:
a portion of the fabricated integrated circuit, and
the entire fabricated integrated circuit.

44. The method of claim 42, further including generating critical parameter vectors according to the at least one criterion.

45. The system of claim 44, wherein the critical parameter vectors test the operating range and stability of at least one selected subsystem of the device under test.

46. The system of claim 45, wherein the at least one selected subsystem is a PLL.

47. The system of claim 44, wherein the critical parameter vectors include measurement of a temperature sensor.

48. The method of claim 44, further including:
applying the thermal stimulation vectors and the critical parameter vectors to the fabricated integrated circuit; and
confirming a value of the at least one criterion based on responses of the integrated circuit to the applied vectors.

49. The method of claim 44, further including:
applying the thermal stimulation vectors and the critical parameter vectors to the fabricated integrated circuit; and
if the fabricated integrated circuit does not meet the at least one criterion in conjunction with the applying, indicating failure.

50. The method of claim 44, further including:
testing the fabricated integrated circuit with the thermal stimulation vectors and the critical parameter vectors; and
if the fabricated integrated circuit is defective according to the at least one criterion, indicating failure.

51. The method of claim 44, further including:
testing the fabricated integrated circuit according to the thermal stimulation vectors;
testing the fabricated integrated circuit according to the critical parameter vectors; and
if the fabricated integrated circuit is defective according to the at least one criterion, reporting a test failure.

52. The method of claim 39, wherein the act of analyzing is based in part on fabrication process parameters.

53. The method of claim 52, wherein the fabrication process parameters describe thermal properties and selected physical dimensions of the components of the fabricated integrated circuit.

54. The method of claim 39, wherein the thermal stimulation vectors include at least a first set and a second set of thermal stimulation vectors adapted to stimulating the fabricated instance of the integrated circuit respectively under a first test scenario and a second test scenario.

55. The method of claim 54, wherein in the first and the second test scenario the fabricated instance of the integrated circuit is respectively in a first unpackaged die embodiment and a second packaged embodiment.

56. The method of claim 54, wherein in the first and the second test scenario the fabricated instance of the integrated circuit is embodied in a package in accordance with respectively a first package physical design and a second package physical design.

57. The method of claim 44, wherein the critical parameter vectors include at least a first set and a second set of critical parameter vectors adapted to evaluating the fabricated instance of the integrated circuit respectively under a first test scenario and a second test scenario.

58. The method of claim 57, wherein in the first and the second test scenario the fabricated instance of the integrated circuit is respectively in a first unpackaged die embodiment and a second packaged embodiment.

59. The method of claim 57, wherein in the first and the second test scenario the fabricated instance of the integrated circuit is embodied in a package in accordance with respectively a first package physical design and a second package physical design.

60. A system for testing integrated circuits having components made in accordance with fabrication process parameters and a layout, the system including:
a device tester adapted to apply test vectors to a device under test, the device under test being one of the integrated circuits;
a repository adapted to store the test vectors;
wherein the test vectors include temperature stimulus vectors and critical parameter vectors generated based on the parameters and the layout;
wherein when applying the test vectors to the device under test the device tester operates the components at respective target temperatures and evaluates the device under test with respect to at least one of a selected standard; and
wherein if the device under test is defective according to the at least one selected standard, the device tester indicates failure of the device under test.

61. The system of claim 60, wherein the selected standard includes at least one of
a worst-case timing path standard,
a best-case timing path standard,
a worst-case threshold voltage standard,
a best-case threshold voltage standard,
a worst-case cross talk noise standard,
a best-case cross talk noise standard,
a worst-case parametric degradation of circuits standard,
a best-case parametric degradation of circuits standard,
a worst-case leakage current standard,
a best-case leakage current standard,
a worst-case voltage drop standard,
a best-case voltage drop standard,
a worst-case power standard,
a best-case power standard,
a highest-gradient temperature standard,
a lowest-gradient temperature standard,
a highest temperature standard, and
a lowest temperature standard.

62. The system of claim 60, wherein the target temperatures are based at least in part on the selected standard.

63. The system of claim 60, wherein the temperature stimulus vectors are thermal stimulation vectors.

64. The system of claim 60, wherein the critical parameter vectors include at-speed vectors.

65. The system of claim 60, wherein the critical parameter vectors include double-clock vectors.

66. The system of claim 60, wherein the critical parameter vectors test the operating range and stability of at least one selected subsystem of the device under test.

67. The system of claim 66, wherein the at least one selected subsystem is a PLL.

68. The system of claim 60, wherein the critical parameter vectors include measurement of a temperature sensor.

69. The system of claim 60, wherein the device tester is adapted to provide a controlled thermal environment for the device under test.

70. The system of claim 69, wherein the controlled thermal environment is maintained at a temperature lower than room temperature.

71. The system of claim 69, wherein the controlled thermal environment is maintained at a temperature higher than room temperature.

72. The system of claim 60, wherein the temperature stimulus vectors include at least a first set and a second set of temperature stimulus vectors adapted to operating the device under test respectively under a first test scenario and a second test scenario.

73. The system of claim 72, wherein in the first and the second test scenario the device under test is respectively in a first unpackaged integrated circuit die embodiment and a second packaged integrated circuit embodiment.

74. The system of claim 72, wherein in the first and the second test scenario the integrated circuit device under test is embodied in a package in accordance with respectively a first package physical design and a second package physical design.

75. The system of claim 60, wherein the critical parameter vectors include at least a first set and a second set of critical parameter vectors adapted to evaluating the device under test respectively under a first test scenario and a second test scenario.

76. The system of claim 75, wherein in the first and the second test scenario the device under test is respectively in a first unpackaged integrated circuit die embodiment and a second packaged integrated circuit embodiment.

77. The system of claim 75, wherein in the first and the second test scenario the integrated circuit device under test is embodied in a package in accordance with respectively a first package physical design and a second package physical design.

78. A system including:
an input/output device to receive a description of an electronic component;
a processor to execute computer programs; and
a computer readable medium to store the computer programs, the computer programs being adapted to execute functions including
performing a thermal analysis of the description of the electronic component, and
generating thermal test vectors according to the thermal analysis and the description of the electronic component.

79. The system of claim 78, wherein the thermal test vectors include vectors to determine if a thermal structure of the electronic component is operating properly.

80. The system of claim 79, wherein:
the thermal structure is a cooling structure;
the thermal test vectors include thermal stimulation vectors to heat circuitry physically near the cooling structure; and
the thermal test vectors further include vectors to determine if the heated circuitry is operating at an expected temperature.

81. The system of claim 79, wherein:
the thermal structure is a heating structure;
the thermal test vectors include thermal stimulation vectors to heat the heating structure; and
the thermal test vectors further include vectors to determine if circuitry physically near the heating structure is operating at an expected temperature.

82. The system of claim 79, wherein:
the thermal structure is a cooling structure;
the thermal test vectors include thermal stimulation vectors to minimize heat generated by circuitry physically near the cooling structure; and
the thermal test vectors further include vectors to determine if the circuitry physically near the cooling structure is operating at an expected temperature.

83. The system of claim 79, wherein:
the thermal structure is a heating structure;
the thermal test vectors include thermal stimulation vectors to minimize heat generated by circuitry physically near the heating structure; and
the thermal test vectors further include vectors to determine if the circuitry physically near the heating structure is operating at an expected temperature.

84. The system of claim 78, wherein the thermal test vectors include thermal stimulation vectors.

85. The system of claim 84, wherein applying the thermal stimulation vectors to the electronic component results in elements of the component operating according to a desired thermal profile.

86. The system of claim 85, wherein the desired thermal profile includes at least one of:
a maximum thermal gradient profile,
a minimum thermal gradient profile,
a maximum absolute thermal profile, and
a minimum absolute thermal profile.

87. The system of claim 78, wherein the thermal test vectors include performance metric measurement vectors to measure a performance metric.

88. The system of claim 87, wherein the performance metric includes at least one of:
a worst-case timing path performance metric,
a best-case timing path performance metric,
a worst-case threshold voltage performance metric,
a best-case threshold voltage performance metric,
a worst-case cross talk noise performance metric,
a best-case cross talk noise performance metric,
a worst-case parametric degradation of circuits performance metric,
a best-case parametric degradation of circuits performance metric,
a worst-case leakage current performance metric,
a best-case leakage current performance metric,
a worst-case voltage drop performance metric,
a best-case voltage drop performance metric,
a worst-case power performance metric,
a best-case power performance metric,
a highest-gradient temperature performance metric,
a lowest-gradient temperature performance metric,
a highest temperature performance metric, and
a lowest temperature performance metric.

89. A computer readable medium containing an executable program to perform thermal test vector generation, wherein the program performs the steps of
generating a first set of vectors to place elements of an integrated circuit at respective operating temperatures;
generating a second set of vectors to control and observe selected critical performance behaviors of the integrated circuit; and
providing the vectors to an output device.

90. The computer readable medium of claim 89, wherein the program further performs the step of receiving an input describing the integrated circuit.

91. The computer readable medium of claim 90, wherein the input describes mask layers used to manufacture a die included in the integrated circuit.

92. The computer readable medium of claim 90, wherein the input describes characteristics of an electronic component package included in the integrated circuit.

93. The computer readable medium of claim 90, wherein:
the integrated circuit includes a die and a package; and
the input characterizes mounting the die in the package.
